(19) United States
(12) Patent Application Publication
(10) Pub. No.: US 2013/0143415 A1
(43) Pub. Date: Jun. 6, 2013

(54) Multi-Component Film Deposition

(71) Applicants: Joseph Yudovsky, Campbell, CA (US); Mei Chang, Saratoga, CA (US); Steven D. Marcus, San Jose, CA (US); Garry K. Kwong, San Jose, CA (US)

(72) Inventors: Joseph Yudovsky, Campbell, CA (US); Mei Chang, Saratoga, CA (US); Steven D. Marcus, San Jose, CA (US); Garry K. Kwong, San Jose, CA (US)

(73) Assignee: Applied Materials, Inc., Santa Clara, CA (US)

(21) Appl. No.: 13/308,849

(22) Filed: Dec. 1, 2011

(51) Int. Cl. H01L 21/31; B67D 7/06; C23C 16/455

(52) U.S. Cl. 438/765; 118/729; 118/723 R; 118/724; 222/129; 257/E21.24

(57) ABSTRACT

Provided are atomic layer deposition apparatus and methods including a gas distribution plate comprising a plurality of elongate gas ports including at least one first reactive gas port in fluid communication with a first reactive gas and at least one second reactive gas port in fluid communication with a gas manifold. The gas manifold is in fluid communication with at least a second reactive gas different from the first reactive gas and a purge gas. Also provided are atomic layer deposition apparatus and methods including linear energy sources in one or more of region before the gas distribution plate and a region after the gas distribution plate.

### BACKGROUND

Embodiments of the invention generally relate to an apparatus and a method for depositing materials. More specifically, embodiments of the invention are directed to a atomic layer deposition chambers with linear reciprocal motion.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are introduced into a process chamber containing a substrate. Generally, a first reactant is introduced into a process chamber and is adsorbed onto the substrate surface. A second reactant is introduced into the process chamber and reacts with the first reactant to form a deposited material. A purge step may be carried out to ensure that the only reactions that occur are on the substrate surface. The purge step may be a continuous purge with a carrier gas or a pulse purge between the delivery of the reactant gases.

There is an ongoing need in the art for improved apparatuses and methods for processing substrates by atomic layer deposition.

### SUMMARY

Embodiments of the invention are directed to gas distribution plates. The gas distribution plates comprise a plurality of elongate gas ports including at least one first reactive gas port in fluid communication with a first reactive gas and at least one second reactive gas port in fluid communication with a gas manifold. The gas manifold in fluid communication with at least a second reactive gas different from the first reactive gas and a purge gas.

In some embodiment, the gas manifold is in fluid communication with a third reactive gas different from the first reactive gas and the second reactive gas and optionally a fourth reactive gas different from the first reactive gas, the second reactive gas and the third reactive gas.

In one or more embodiments, the manifold comprises at least one switching valve configured to block fluid communication between the gas manifold and each of the second reactive gas and the purge gas so that no gas or a single gas as in flow communication with the manifold.

In some embodiments, there is a leading second reactive gas port and a trailing second reactive gas port with a first reactive gas port on either side of the leading second reactive gas port and the trailing second reactive gas port. In detailed embodiments, the leading second reactive gas port is in fluid communication with a leading gas manifold and the trailing second reactive gas port is in fluid communication with a trailing gas manifold, the leading gas manifold being in fluid communication with at least a second reactive gas, a purge gas and at least one additional leading reactive gas different from the first reactive gas and the second reactive gas, and the trailing gas manifold in fluid communication with at least a second reactive gas, a purge gas and at least one additional trailing reactive gas different from the first reactive gas and the second reactive gas. In specific embodiments, the additional leading reactive gas and the additional trailing reactive gas are the same. In certain embodiments, the additional leading reactive gas is different from the additional trailing reactive gas.

In some embodiments, a substrate moving from a region in front of the gas distribution plate to a region behind the gas distribution plate is exposed to the plurality of gas injectors including, in order, a leading first reactive gas port followed by at least one second reactive gas port unit. The second reactive gas port unit consists essentially of (1) the second reactive gas port in fluid communication with a gas manifold, the gas manifold in fluid communication with at least a reactive gas different from the first reactive gas and a purge gas, and (2) a trailing first reactive gas port.

In detailed embodiments, the manifold of each of the at least one second reactive gas port units is in fluid communication with at least one additional reactive gas. In specific embodiments, there is one second reactive gas port unit. In certain embodiments, there are at least two second reactive gas port units. In one or more embodiments, each of the second reactive gas port units comprises a different reactive gas.

In some embodiments, a substrate moving from a region in front of the gas distribution plate to a region in back of the gas distribution plate is exposed, in order, to the plurality of gas injectors. The plurality of gas injectors consist essentially of: a leading first reactive gas port; a leading second reactive gas port in fluid communication with a leading gas manifold, the leading gas manifold in fluid communication with at least a second reactive gas different from the first reactive gas and a purge gas; an intermediate first reactive gas port; a trailing second reactive gas port in fluid communication with a trailing gas manifold, the trailing gas manifold in fluid communication with at least a third reactive gas and a purge gas, the third reactive gas being different from the first reactive gas and the second reactive gas; and a trailing first reactive gas port.

Additional embodiments of the invention are directed to atomic layer deposition systems. The ALD systems comprise a processing chamber with a gas distribution plate as described therein and a substrate carrier configured to move a substrate reciprocally with respect to the gas distribution plate in a back and forth motion perpendicular to an axis of the elongate gas ports.

In some embodiments of the ALD system, the gas manifold is in fluid communication with at least a third reactive gas different from the second reactive gas and the first reactive gas.

One or more embodiments of the ALD system further comprises at least one energy source located in one or more of a region before the gas distribution plate and a region after the gas distribution plate. In detailed embodiments, the at least one energy source is selected from the group consisting of resistive heaters, radiative heaters, ultraviolet sources, laser sources, flash lamp, linear light sources and combinations thereof.

Further embodiments of the invention are directed to methods of processing a substrate. A portion of the substrate is passed across a gas distribution plate in a first direction. The portion of the substrate is exposed to, in order, a leading first reactive gas stream from a leading first reactive gas port, a second reactive gas stream different from the first reactive gas stream from a second reactive gas port and a trailing first reactive gas stream from a trailing first reactive gas port to deposit a first layer. The second reactive gas stream is purged from the second reactive gas port. A third reactive gas is provided through the second reactive gas port. The third reactive gas being different from the first reactive gas and the second reactive gas. The portion of the substrate is passed across the gas distribution plate in a second direction opposite the first direction so that the portion of the substrate is exposed to, in order, the trailing first reactive gas stream from the trailing first reactive gas port, the third reactive gas stream from the second reactive gas port and the leading first reactive gas stream from the leading first reactive gas port to create a second layer.

Some embodiments further comprise exposing the portion of the substrate to a purge gas stream between each of the first reactive gas streams and the second reactive gas stream and between each of the first reactive gas streams and the third reactive gas stream.

Additional embodiments of the invention are directed to methods of processing a substrate. A portion of the substrate is passed across a gas distribution plate in a first direction so that the portion of the substrate is exposed to, in order, a leading first reactive gas stream from a leading first reactive gas port, a leading second reactive gas stream from a second reactive gas port, an intermediate first reactive gas stream from an intermediate first reactive gas port, a purge gas from a trailing second reactive gas port and a trailing first reactive gas stream from a trailing first reactive gas port. The second reactive gas stream is purged from the leading second reactive gas port so that a purge gas flows from the leading second reactive gas port. The purge gas flowing from the trailing second reactive gas port is changed to a third reactive gas different from the first reactive gas and the second reactive gas. The portion of the substrate is passed across the gas distribution plate in a second direction opposite of the first direction so that the portion of the substrate is exposed to, in order, a trailing first reactive gas stream from a trailing first reactive gas port, a third reactive gas stream from the trailing second reactive gas port, an intermediate first reactive gas stream from the intermediate first reactive gas port, a purge gas stream from the leading second reactive gas port and a leading first reactive gas stream from a leading first reactive gas port.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic side view of an atomic layer deposition chamber according to one or more embodiments of the invention;

FIG. 2 shows a susceptor in accordance with one or more embodiments of the invention;

FIG. 3 show a partial perspective view of an atomic layer deposition chamber in accordance with one or more embodiments of the invention;

FIGS. 4A and 4B show a views of a gas distribution plate in accordance with one or more embodiments of the invention;

FIG. 5 shows a schematic cross-sectional view of a gas distribution plate in accordance with one or more embodiments of the invention;

FIG. 6 shows a schematic cross-sectional view of a gas distribution plate in accordance with one or more embodiments of the invention;

FIG. 7 shows a schematic cross-sectional view of a gas distribution plate with associated gas manifold in accordance with one or more embodiments of the invention;

FIG. 8 shows a schematic cross-sectional view of a gas distribution plate with associated gas manifolds in accordance with one or more embodiments of the invention;

FIG. 9 shows a schematic cross-sectional view of a gas distribution plate with associated gas manifolds in accordance with one or more embodiments of the invention;

FIG. 10 shows a view of a processing chamber in accordance with one or more embodiments of the invention; and

FIG. 11 shows a cluster tool in accordance with one or more embodiment of the invention.

### DETAILED DESCRIPTION

Embodiments of the invention are directed to atomic layer deposition apparatus and methods which provide improved movement of substrates. Specific embodiments of the invention are directed to atomic layer deposition apparatuses (also called cyclical deposition) incorporating a gas distribution plate having a detailed configuration and reciprocal linear motion.

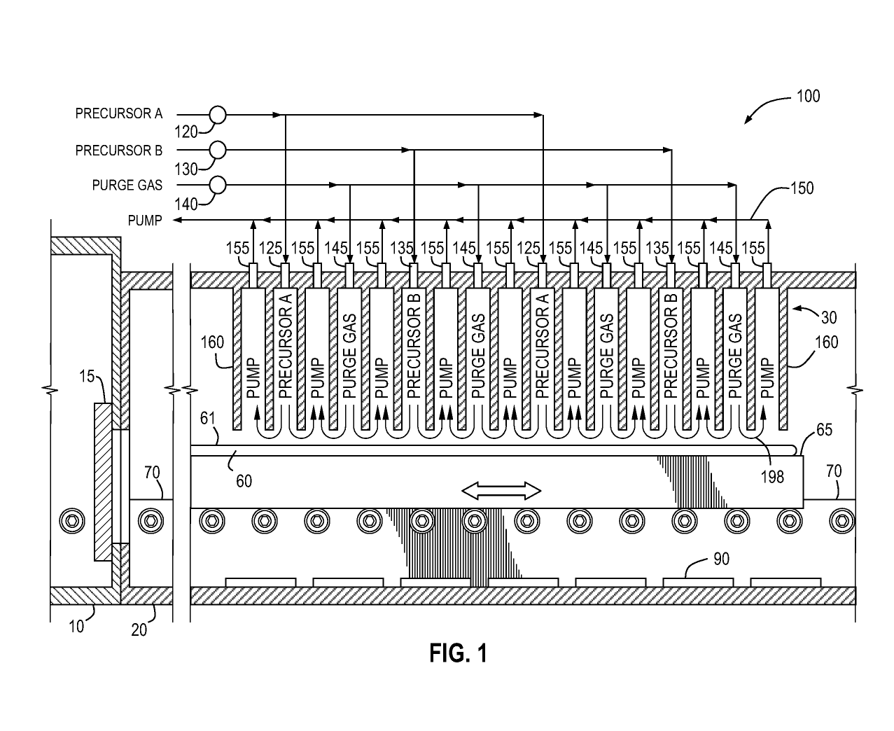

FIG. 1 is a schematic cross-sectional view of an atomic layer deposition system 100 or reactor in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

The gas distribution plate 30 comprises a plurality of gas ports configured to transmit one or more gas streams to the substrate 60 and a plurality of vacuum ports disposed between each gas port and configured to transmit the gas streams out of the processing chamber 20. In the detailed embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A into the processing chamber 20 through a plurality of gas ports 125. The precursor injector 130 is configured to inject a continuous (or pulse) stream of a reactive precursor of compound B into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and/or the precursor injector 130 prior to injecting the precursors into the chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc. In further embodiments, a direct plasma source (not shown) is connected to the precursor injector 120 and/or the precursor injector 130 prior to injecting the precursors in the chamber 20. The direct plasma source can be incorporated into the gas distribution plate 30 so that the plasma is generated in the gas distribution plate. Embodiments of this sort can be configured so that the electrodes necessary for forming the plasma are distributed within one or more of the gas distribution plate, the substrate support and the chamber. Various forms of generating and transferring radicals and ions to the substrate can be incorporated into the system 100 to allow for the use of plasma enhanced deposition methods.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60, for example about 0.5 mm from the first surface 61, This distance should be such that the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas distribution systems may be employed.

In operation, a substrate 60 is delivered (e.g., by a robot) to the load lock chamber 10 and is placed on a carrier 65. After the isolation valve 15 is opened, the carrier 65 is moved along the track 70, which may be a rail or frame system. Once the carrier 65 enters in the processing chamber 20, the isolation valve 15 closes, sealing the processing chamber 20. The carrier 65 is then moved through the processing chamber 20 for processing. In one embodiment, the carrier 65 is moved in a linear path through the chamber.

As the substrate 60 moves through the processing chamber 20, the first surface 61 of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the first surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discrete steps.

Sufficient space is generally provided at the end of the processing chamber 20 so as to ensure complete exposure by the last gas port in the processing chamber 20. Once the substrate 60 reaches the end of the processing chamber 20 (i.e., the first surface 61 has completely been exposed to every gas port in the chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are configured so as not to remove adsorbed precursors from the substrate surface 110. The width between each partition, the number of gas ports disposed on the processing chamber 20, and the number of times the substrate is passed back and forth may also determine the extent to which the substrate surface 110 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 110 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward.

In yet another embodiment, the system 100 may be configured to process a plurality of substrates. In such an embodiment, the system 100 may include a second load lock chamber (disposed at an opposite end of the load lock chamber 10) and a plurality of substrates 60. The substrates 60 may be delivered to the load lock chamber 10 and retrieved from the second load lock chamber.

In one or more embodiments, at least one radiant heat lamp 90 is positioned to heat the second side (or back side) of the substrate. The radiant heat source is generally positioned on the opposite side of the gas distribution plate 30 from the substrate 60. In these embodiments, the gas cushion plate is made from a material which allows transmission of at least some of the light from the radiant heat source. For example, the gas cushion plate can be made from quartz, allowing radiant energy from a visible light source to pass through the plate and contact the back side of the substrate and cause an increase in the temperature of the substrate.

In some embodiments, the carrier 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

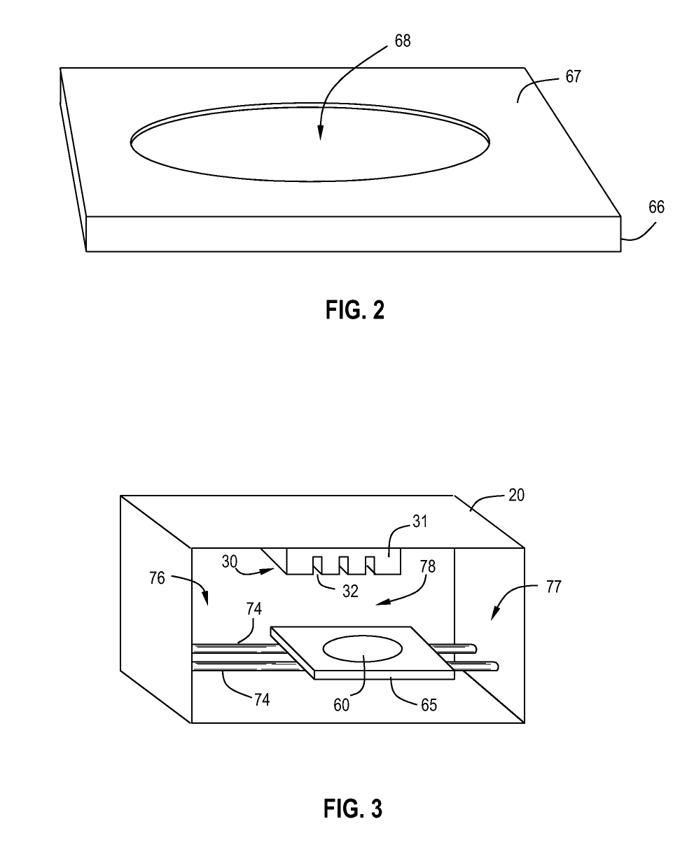

In still another embodiment, the top surface 67 of the susceptor 66 includes a recess 68 configured to accept the substrate 60, as shown in FIG. 2. The susceptor 66 is generally thicker than the thickness of the substrate so that there is susceptor material beneath the substrate. In detailed embodiments, the recess 68 is configured such that when the substrate 60 is disposed inside the recess 68, the first surface 61 of substrate 60 is level with the top surface 67 of the susceptor 66. Stated differently, the recess 68 of some embodiments is configured such that when a substrate 60 is disposed therein, the first surface 61 of the substrate 60 does not protrude above the top surface 67 of the susceptor 66.

FIG. 3 shows a partial cross-sectional view of a processing chamber 20 in accordance with one or more embodiments of the invention. The diagram of FIG. 3 is clearly not to scale, but is shown for descriptive purposes only. The processing chamber 20 has a gas distribution plate 30 with at least one gas injector unit 31. As used in this specification and the appended claims, the term “gas injector unit” is used to describe a sequence of gas ports (also referred to gas outlets) in a gas distribution plate 30 which are capable of depositing a discrete film on a substrate surface. For example, if a discrete film is deposited by combination of two components, then a single gas injector unit would include gas ports for at least those two components. A gas injector unit 31 can also include any purge gas ports or vacuum ports within and around the gas outlets capable of depositing a discrete film. For example, the gas distribution plate 30 shown in FIG. 1 has two gas injector units 31 visible (with each AB combination being a single injector unit), but it should be understood that any number of gas injector units 31 could be part of the gas distribution plate 30.

In some embodiments, the processing chamber 20 includes a substrate carrier 65 which is configured to move a substrate along a linear reciprocal path along an axis perpendicular to the elongate gas ports. As used in this specification and the appended claims, the term “linear reciprocal path” refers to either a straight or slightly curved path in which the substrate can be moved back and forth. Stated differently, the substrate carrier may be configured to move a substrate reciprocally with respect to the gas injector unit in a back and forth motion perpendicular to the axis of the elongate gas ports. As shown in FIG. 3, the carrier 65 is supported on rails 74 which are capable of moving the carrier 65 reciprocally from left-to-right and right-to-left, or capable of supporting the carrier 65 during movement. Movement can be accomplished by many mechanisms known to those skilled in the art. For example, a stepper motor may drive one of the rails, which in turn can interact with the carrier 65, to result in reciprocal motion of the substrate 60. In detailed embodiments, the substrate carrier is configured to move a substrate 60 along a linear reciprocal path along an axis perpendicular to and beneath the elongate gas ports 32. In specific embodiments, the substrate carrier 65 is configured to transport the substrate 60 from a region 76 in front of the gas distribution plate 30 to a region 77 after the gas distribution plate 30 so that the entire substrate 60 surface passes through a region 78 occupied by the gas distribution plate 30.

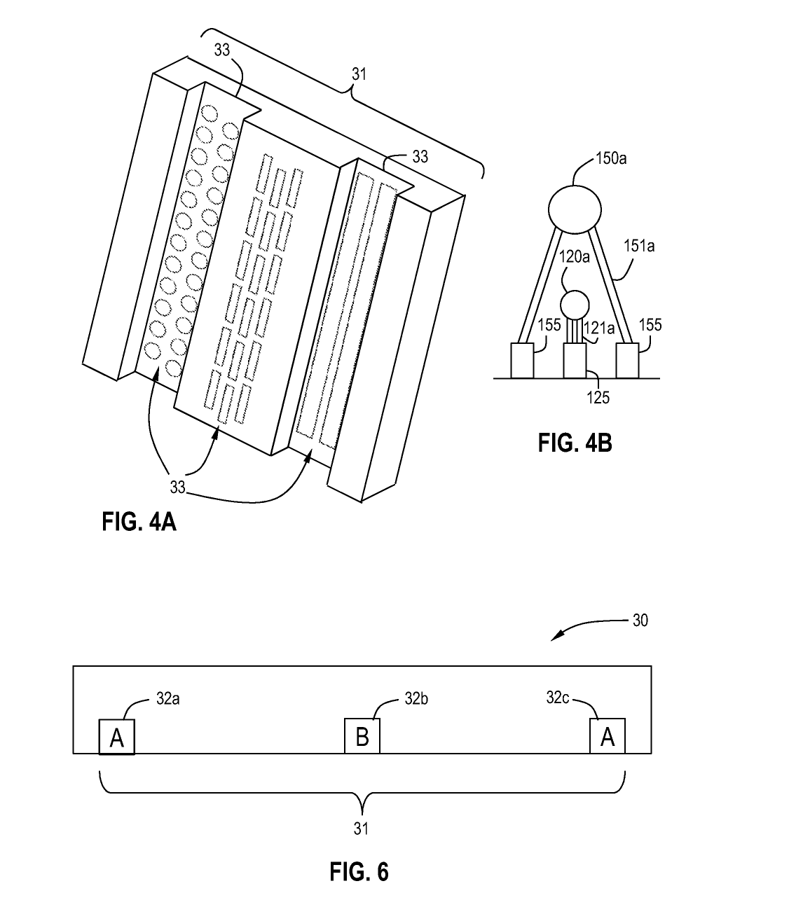

FIG. 4A shows a bottom perspective view of a gas distribution plate 30 in accordance with one or more embodiments of the invention. With reference to both FIGS. 3 and 4, each gas injector unit 31 comprises a plurality of elongate gas ports 32. The elongate gas ports 32 can be in any suitable shape or configuration with examples shown in FIG. 4A. The elongate gas port 32 on the left of the drawing is a series of closely spaced holes. These holes are located at the bottom of a trench 33 formed in the face of the gas distribution plate 30. The trench 33 is shown extending to the ends of the gas distribution plate 30, but it will be understood that this is merely for illustration purposes and the trench does not need to extend to the edge. The elongate gas port 32 in the middle is a series of closely spaced rectangular openings. This injector is shown directly on the face of the gas distribution plate 30 as opposed to being located within a trench 33. The trench 33 of detailed embodiments has about 8 mm deep and has a width of about 10 mm. The elongate gas port 32 on the right of FIG. 4A is shown having two elongate channels.

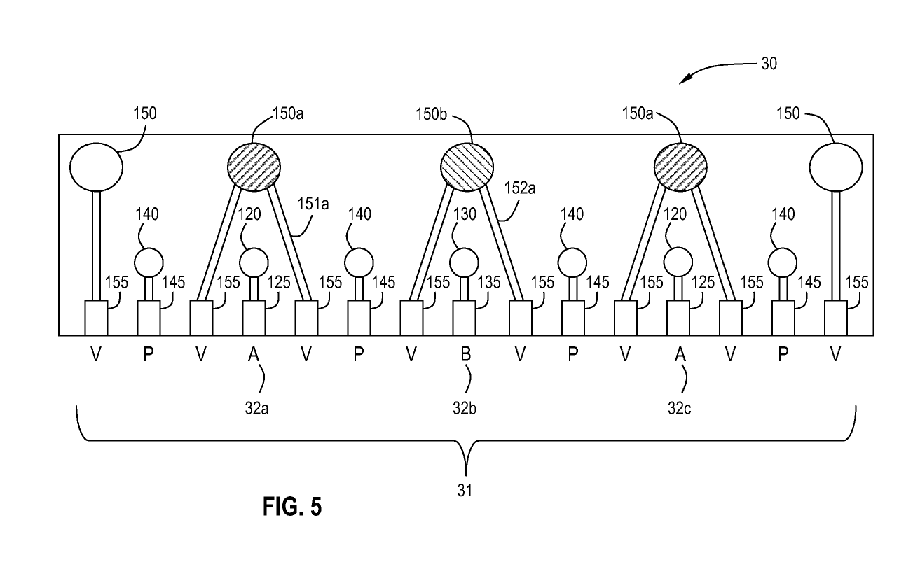

FIG. 4B shows a side view of a portion of the gas distribution plate 30. A larger portion and description is included in FIG. 5. FIG. 4B shows the relationship of a single pumping plenum 150a with the vacuum ports 155. The pumping plenum 150a is connected to these vacuum ports 155 through two channels 151a. These channels 151 are in flow communication with the vacuum ports 155 by the elongate injectors 32 shown in FIG. 4A. In specific embodiments, the elongate injectors 32 have about 28 holes having a diameter of about 4.5 mm. In various embodiments, the elongate injectors 32 have in the range of about 10 to about 100 holes, or in the range of about 15 to about 75 holes, or in the range of about 20 to about 50 holes, or greater than 10 holes, 20 holes, 30 holes, 40 holes, 50 holes, 60 holes, 70 holes, 80 holes, 90 holes or 100 holes. In an assortment of embodiments, the holes have a diameter in the range of about 1 mm to about 10 mm, or in the range of about 2 mm to about 9 mm, or in the range of about 3 mm to about 8 mm, or in the range of about 4 mm to about 7 mm, or in the range of about 5 mm to about 6 mm, or greater than 1 mm, 2 mm, 3 mm, 4 mm, 5 mm, 6 mm, 7 mm, 8 mm, 9 mm or 10 mm. The holes can be lined up in two or more rows, scattered or evenly distributed, or in a single row.

The gas supply plenum 120a shown in FIG. 4B is connected to the elongate gas port 32 by two channels 121a. Although it will be understood by those skilled in the art that there can be any number of channels. In detailed embodiments, the gas supply plenum 120a has a diameter of about 14 mm. In various embodiments, the gas supply plenum has a diameter in the range of about 8 mm to about 20 mm, or in the range of about 9 mm to about 19 mm, or in the range of about 10 mm to about 18 mm, or in the range of about 11 mm to about 17 mm, or in the range of about 12 mm to about 16 mm, or in the range of about 13 mm to about 15 mm, or greater than 4 mm, 5 mm, 6 mm, 7 mm, 8 mm, 9 mm, 10 mm, 11 mm, 12 mm, 13 mm, 14 mm, 15 mm, 16 mm, 17 mm, 18 mm, 19 mm or 20 mm. In specific embodiments, the channels 121a have a diameter about 0.5 mm and there are about 121 of these channels in two rows, either staggered or evenly spaced. In various embodiments, the diameter is in the range of about 0.1 mm to about 1 mm, or in the range of about 0.2 mm to about 0.9 mm, or in the range of about 0.3 mm to about 0.8 mm or in the range of about 0.4 mm to about 0.7 mm, or greater than 0.2 mm, 0.3 mm, 0.4 mm, 0.5 mm, 0.6 mm, 0.7 mm, 0.8 mm, 0.9 mm or 1 mm. Although the gas supply plenum 120a is associated numerically with the first precursor gas, it will be understood that similar configurations may be made for the second reactive gases and the purge gases. Without being bound by any particular theory of operation, it is believed that the dimensions of the plenums, channels and holes define the conductance of the channels and uniformity.

The letters used in these drawings represent some of the different gases which may be used in the system. As a reference, A is a first reactive gas, B is a second reactive gas, C is a third reactive gas, P is a purge gas and V is vacuum. As used in this specification and the appended claims, the term “reactive gas” refers to any gas which may react with either the substrate, a film or partial film on the substrate surface. Non-limiting examples of reactive gases include organometallic precursors, tantalum precursors, hafnium precursors, water, cerium precursors, peroxide, titanium precursors, aluminum precursors, silicon precursors, boron precursors, oxygen precursors, carbon precursors, nitrogen precursors, ozone, plasmas, precursors including Groups III-V elements, precursors for the formation of aluminum-titanium alloys, tantalum silicide, hafnium borooxides, silicon carbides and silicon carbonitrides. Purge gases are any gas which is non-reactive with the species or surface it comes into contact with. Non-limiting examples of purge gases include argon, nitrogen and helium.

FIG. 5 shows a detailed embodiment of the gas distribution plate 30. As shown here, the gas distribution plate 30 comprises a single gas injector unit 31 which may include the outside purge gas P injectors and outside vacuum V ports. In the detailed embodiment shown, the gas distribution plate 30 comprises at least two pumping plenums connected to the pumping system 150. The first pumping plenum 150a is in flow communication with the vacuum ports 155 adjacent to (on either side of) the gas ports 125 associated with the first reactive gas A injectors 32a, 32c. The first pumping plenum 150a is connected to the vacuum ports 155 through two vacuum channels 151a. The second pumping plenum 150b is in flow communication with the vacuum ports 155 adjacent to (on either side of) the gas port 135 associated with the second reactive gas B injector 32b. The second pumping plenum 150b is connected to the vacuum ports 155 through two vacuum channels 152a. In this manner, the first reactive gas A and the second reactive gas B are substantially prevented from reacting in the gas phase. The vacuum channels in flow communication with the end vacuum ports 155 can be either the first vacuum channel 150a or the second vacuum channel 150b, or a third vacuum channel. The pumping plenums 150, 150a, 150b can have any suitable dimensions. The vacuum channels 151a, 152a can be any suitable dimension. In specific embodiments, the vacuum channels 151a, 152a have a diameter of about 22 mm. The end vacuum plenums 150 collect substantially only purge gases. An additional vacuum line collects gases from within the chamber. These four exhausts (A, B, purge gas and chamber) can be exhausted separately or combined downstream to one or more pumps, or in any combination with two separate pumps.

In some embodiments, the reactive gas ports on either end of the gas distribution plate 30 are the same so that the first and last reactive gas seen by a substrate passing the gas distribution plate 30 is the same. For example, if the first reactive gas is A, then the last reactive gas will also be A. If gas A and B are switched, then the first and last gas seen by the substrate will be gas B. This processing scheme may be referred to as reciprocal processing.

FIG. 6 shows a schematic of a basic gas injector unit 31 in accordance with some embodiments. The gas injector unit 31 shown comprises a plurality of elongate gas ports including at least two first reactive gas ports A and at least one second reactive gas port B which is a different gas than that of the first reactive gas ports. The first reactive gas ports A are in fluid communication with a first reactive gas, and the second reactive gas ports B are in fluid communication with a second reactive gas which is different from the first reactive gas. The two first reactive gas ports A surround the second reactive gas port B so that a substrate moving from left-to-right will see, in order, the leading first reactive gas A, the second reactive gas B and the trailing first reactive gas A, resulting in a full layer being formed on the substrate. A substrate returning along the same path will see the opposite order of reactive gases, resulting in two layers for each full cycle. As a useful abbreviation, this configuration may be referred to at an ABA injector configuration. A substrate moved back and forth across this gas injector unit 31 would see a pulse sequence of

AB AAB AAB(AAB)ₙ . . . AABA

forming a uniform film composition of B. Exposure to the first reactive gas A at the end of the sequence is not important as there is no follow-up by a second reactive gas B. It will be understood by those skilled in the art that while the film composition is referred to as B, it is really a product of the surface reaction products of reactive gas A and reactive gas B and that use of just B is for convenience in describing the films.

It can be seen that inclusion of additional precursors for the preparation of multi-component films can result in very large gas distribution plates. Each additional component may require two or more gas ports to deposit the desired material. For example, depositing a strontium titanate film might require gas ports for a titanium precursor followed by an oxidant (ozone or water) and a strontium precursor followed by an oxidant (ozone). This requires a minimum of four gas ports for a single directional pass beneath the gas distribution plate. For a reciprocal process (meaning at least one back and forth pass beneath the gas distribution plate) there would need to be even more gas ports. This does not even include additional alumina deposition cycles or annealing processes which can further increase the size of the gas distribution plate. Similarly, films having three or more components (e.g., barium strontium titanate and lead zirconium titanate films) would require even larger gas distribution plates. Accordingly, one or more embodiments of the invention are directed to multi-component injectors for reciprocal atomic layer deposition processing requiring less gas ports.

In general, embodiments of the invention are based on a spatial ALD gas distribution plate with the addition of separated precursor lines added to enable switching to a new precursor as demanded. Annealing capability can also be added at the end of the injector or in the middle of pump/purge channels.

One or more embodiments of the invention are directed to methods of processing a substrate. A portion of a substrate is passed across a gas distribution plate in a first direction. As used in this specification and the appended claims, the term “passed across” means that the substrate has been moved over, under, etc., the gas distribution plate so that gases from the gas distribution plate can react with the substrate or layer on the substrate. In moving the substrate in the first direction, the substrate is exposed to, in order, a leading first reactive gas stream, a second reactive gas stream and a trailing first reactive gas stream to deposit a first layer. The portion of the substrate is then passed across the gas distribution plate in a direction opposite of the first direction so that the portion of the substrate is exposed to, in order, the trailing first reactive gas stream, the second reactive gas stream and the leading first reactive gas stream to create a second layer

In detailed embodiments, the method further comprises exposing the portion of the substrate to a purge gas stream between each of the first reactive gas streams and the second reactive gas streams. The gases of some embodiments are flowing continuously. In some embodiments, the gases are pulsed as the substrate moves beneath the gas distribution plate.

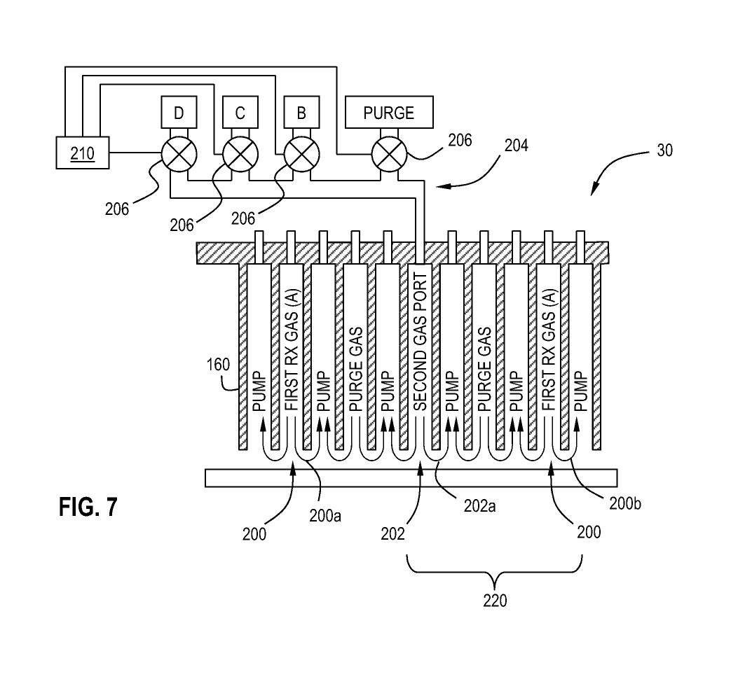

FIGS. 7-9 show side, partial cross-sectional views of gas distribution plates 30 in accordance with various embodiments of the invention. It should be noted that the Figures show a partial gas distribution plate 30 and may not include all of the gas ports. For example, there may be additional purge and pump ports on either side of the gas distribution plate 30 shown.

In a broad sense and with reference to FIG. 7, embodiments of the invention are directed to a gas distribution plate 30 comprising a plurality of elongate gas ports. FIG. 7 shows a single precursor injector with gas alternation by valves. The plurality of elongate gas ports include at least one first reactive gas port 200 (referred to as “FIRST RX GAS (A)” in the figures) and at least one second reactive gas port 202 (referred to as “SECOND GAS PORT” in the figures). The first reactive gas ports 200 are configured to flow a first reactive gas A toward the surface of substrate 60. The second reactive gas port 202 is configured to flow a second gas (which can be reactive or inert) toward the surface of the substrate 60. The terms “reactive gas” and “precursor” may be used interchangeably throughout the specification. As has been shown in FIG. 1, each of the gas ports are separated from adjacent gas ports by partitions 160.

The second reactive gas port 202 is connected to and in fluid communication with a gas manifold 204. It will be understood by those skilled in the art, that the gas manifold 204 in fluid communication with the second reactive gas port 202 allows the gas in the second reactive gas port to be changed. The second reactive gas port 202 is configured to flow the gas from the gas manifold 204 toward the surface of the substrate 60. The gas manifold 204 can be any suitable manifold capable of merging and controlling the flows of more than one gas. The gas manifold is in fluid communication with at least a second reactive gas B and a purge gas P. The second reactive gas B is different from the first reactive gas A and the purge gas P.

The gas manifold 204 shown in FIG. 7 is connected to four different gas sources. The gas sources can be any suitable gas sources including, but not limited to, cylinders of compressed gas and gas generators suitable for generating the desired gaseous species. The gas manifold of the detailed embodiment shown is in fluid communication with a purge gas P, a second reactive gas B, a third reactive gas C and a fourth reactive gas D. It will be understood by those skilled in the art that there can be any number of gases in fluid communication with the gas manifold 204 and that the gas manifold shown in FIG. 7 is merely one possible arrangement. In some embodiments, the gas manifold 204 is in fluid communication with a purge gas P, a second reactive gas B, a third reactive gas C and, optionally, a fourth reactive gas D. The arrangement shown in FIG. 7 is merely illustrative and can be reordered. For example, it may be useful to have the purge gas P located at the farthest point on the gas manifold 204 from the second reactive gas port 202 so that when the purge gas is flowed it can more easily remove any residual reactive gases from the gas manifold 204.

The first reactive gas A, second reactive gas B, third reactive gas C, fourth reactive gas D, etc., are different from each other. The differences are generally in the chemical species, but may also be in the concentration of the reactive species. For example, the second reactive gas B and the third reactive gas C may be the same species with one having a concentration of 1000 ppm in an inert gas and the other having a concentration of 100 ppm in the same or different inert gas. Those skilled in the art will recognize that the concentrations of the gases are not limited to the examples above.

The gas manifold 204 in some embodiments comprises at least one switching valve 206. The switching valve 206 is configured to block fluid communication between the gas manifold 204 and each of the second reactive gas B and the purge gas P so that no gas or only a single gas is in flow communication with the gas manifold 204 and therefore no gas or only a single gas is in flow communication with the second gas port 202. Generally, each individual gas source will be connected to the gas manifold through a switching valve 206 so that the identity of the gaseous species can be controlled. In some embodiments, the purge gas is connected to the gas manifold without a switching valve present so that there is always a flow of gas through the gas manifold 204 and through the second gas port 202. Those skilled in the art will understand that there may also be a master control for any or all of the gases so that the flow can be stopped. The gas manifold 204 may be only one of several gas control systems that are employed.

The switching valve 206 can be any suitable device capable of regulating the flow of gas from the source to the gas manifold 204. The switching valve 206 can be, for example, a manually operated needle valve, ball valve, or automated needle valves, ball valves, gate valves, flow limiters and mass flow controllers. In automated systems, the switching valves 206 may be controlled by a controller 210 with can be hardware and/or software based. This allows for process automation and helps minimize the effect of user error from manual valve control.

In use, a substrate 60 is passed across the gas distribution plate 30 in a first direction. For convenience, the first direction will be designated as left-to-right on FIG. 7. The substrate, or portion of the substrate, is exposed to, in order, the leading first reactive gas stream A 200a flowing from the leading first reactive gas port 200. The first reactive gas A can interact with the substrate surface in a first part of the ALD reaction. As used in this specification and the appended claims, the terms leading, trailing, intermediate, and the like, are intended only to differentiate the position of the individual gas ports or the order in which the gases from the individual gas ports contact the substrate. The substrate surface, or portion of the substrate surface, is then exposed to a second reactive gas stream B 202a from a second reactive gas port 202. The second reactive gas B stream 202a being different from the first reactive gas A stream 200a and interacting with the first part of the ALD reaction formed on the surface of the substrate 60 to create a B layer. As will be understood by those skilled in the art, the “second reactive gas stream” can, in fact, be a purge gas, which is not actually reactive. The term “second reactive gas stream” is used to describe a gas flow emitted by a gas port which may also be used to emit a reactive gas stream. The term “second reactive gas port” is used to describe a gas port in fluid communication with the gas manifold as described. The substrate 60 is then exposed to a trailing first reactive gas stream 200b which may form a partial ALD layer on the substrate 60.

The second reactive gas B stream 202a is purged from the second reactive gas port 202 by flowing the purge gas P through the gas manifold 204. From a control standpoint, the gas manifold initially was flowing either the second reactive gas B or a combination of the second reactive gas B and the purge gas P. Purging the manifold means that the second reactive gas B flow is discontinued and the purge gas P flow is allowed to remove residual second reactive gas B from the manifold. A third reactive gas C is then provided through the gas manifold to the second reactive gas port 202. The third reactive gas C is different from the first reactive gas A and the second reactive gas B. This can be accomplished by either ceasing the flow of purge gas P through the manifold by closing the valve 206 on the purge line or allowing the flow of purge gas P to continue and opening the valve 206 for the third reactive gas C to allow the gas to flow from the gas source through the gas manifold and into the processing chamber.

The substrate, or portion of the substrate, is passed across the gas distribution plate in a second direction opposite of the first direction. Again, for convenience, the second direction is shown as from right-to-left on FIG. 7. Thus, the substrate surface is exposed first to the trailing first reactive gas A stream 200b from the trailing first reactive gas port 200. The first reactive gas A forming the first part of an ALD reaction on the substrate surface. The substrate, or portion of the substrate, is then exposed to the third reactive gas C stream flowing from the second reactive gas port 202. The third reactive gas C reacts with the first part of the ALD reaction already on the substrate to form a C film. The substrate, or portion of the substrate is then exposed to the leading first reactive gas A stream 200a from the leading first reactive gas port 200. Therefore, one cycle (i.e., one movement from left-to-right followed by one movement from right-to-left) would result in one B layer and one C layer. This may be referred to as BC deposition.

Those skilled in the art will understand that substrate may make many cycles with the second reactive gas B flowing through the second reactive gas port 202 to create a thicker layer of B. The second reactive gas B can be then replaced with the third reactive gas C and the substrate can many any number of cycles to create a thicker layer of C.

The purge gas ports and pump ports are shown between each of the reactive gas ports. The function and use of these ports is the same as that described with respect to FIG. 1. In detailed embodiments, the substrate, or portion of the substrate is exposed to a purge gas stream between each of the first reactive gas streams and the second reactive gas stream and between each of the first reactive gas streams and the third reactive gas stream. The purge gas stream is shown as a purge gas port surrounded by pump ports on either side. Without being bound by any particular theory of operation, it is believed that this combination of gas ports results in the smooth gas flows shown by the arrow paths in the Figures.

While not necessary, the embodiments shown have a first reactive gas A port 200 on either side of the second reactive gas port 202. This is a particularly useful configuration for reciprocal processing. However, it is not necessary for the first reactive gas ports to bookend the second reactive gas port. In some embodiment, the first reactive gas port and the second reactive gas port are present in equal numbers. For example, a large gas distribution plate may have 30 gas ports for the first reactive gas alternating with 30 gas ports for the second reactive gas. Thus, a single pass of the substrate would result in 30 B layers deposited on the substrate.

In a detailed embodiment, a substrate moving from a region in front of the gas distribution plate 30 to a region in back of the gas distribution plate 30 is exposed to the plurality of gas ports. The gas ports that the substrate would encounter, in order, are a leading first reactive gas A port 200 followed by at least one second reactive gas port unit 220. The second reactive gas port unit 220 consists essentially of (1) a second reactive gas port 202 in fluid communication with a gas manifold 204 as described above and a trailing first reactive gas A port 200. The embodiment shown in FIG. 7 includes a single second reactive gas port unit 220, but it can be easily seen that any number of units can be repeated to form a longer gas distribution plate 30 in which a single pass would deposit a thicker layer. In detailed embodiments, the gas manifold 204 of each of the at least one second reactive gas port units 220 is in fluid communication with at least one additional reactive gas (e.g., a third reactive gas C and/or a fourth reactive gas D). In specific embodiments, there are at least two second reactive gas units 220. In certain embodiments, each of the second reactive gas port units 220 comprises a different reactive gas. For example, if there are two reactive gas port units 220 then one might include a third reactive gas C and the other might include a fourth reactive gas D.

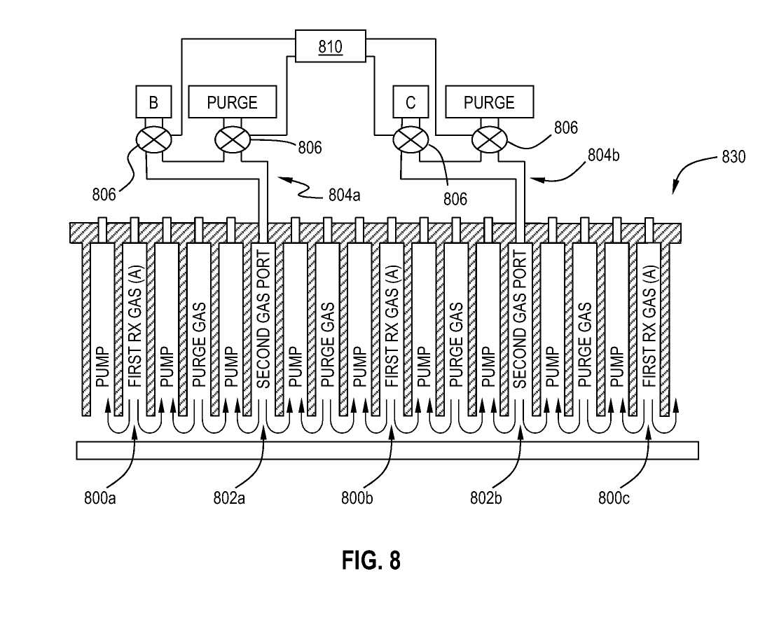

FIG. 8 shows another embodiment of the invention with dual precursor injectors with gas alternation by the valves. The embodiment shown can generate a B/C layer with ratio equal to 1:1 with no precursor alternation needed. The gas distribution plate 830 comprises a plurality of gas ports. The gas distribution plate 830 shown has a leading second reactive gas port 802a and a trailing second reactive gas port 802b with a first reactive gas port 800a, 800b, 800c on either sides of the leading second reactive gas port 802a and the trailing second reactive gas port. Stated differently, a substrate passing the gas distribution plate 830 would encounter, in order, a leading first reactive gas port 800a, a leading second reactive gas port 802a, an intermediate first reactive gas port 800b, a trailing second reactive gas port 802b and a trailing first reactive gas port 800c. The substrate will also encounter purge ports and pump ports between the reactive gas ports.

The leading second reactive gas port 802a is in fluid communication with a leading gas manifold 804a and the trailing second reactive gas port 802b is in fluid communication with a trailing gas manifold 804b. The leading gas manifold 804a is in fluid communication with at least a second reactive gas B source and a purge gas P source. The trailing gas manifold 804b is in fluid communication with at least a third reactive gas C source and a purge gas P source.

In use, both the leading second reactive gas port 802a and the trailing second reactive gas port 802b can be delivering a reactive gas (i.e., non-purge gas) simultaneously. Ignoring purge and pump ports, a substrate passing from left-to-right would encounter a first reactive gas A stream from a leading first reactive gas port 800a to make a partial ALD layer on the substrate. The substrate would then encounter a second reactive gas B stream from the leading second reactive gas port 802a. The second reactive gas B reacting with the partial ALD layer on the substrate to form a layer of B on the substrate. The substrate then encounters a first reactive gas A stream from the intermediate first reactive gas port 800b to form a partial ALD layer on the substrate surface having the layer of B thereon. The substrate then encounters a third reactive gas C stream from the trailing second reactive gas port 802b. The third reactive gas C reacts with the partial ALD layer on the substrate to form a layer of C on the substrate surface. Lastly, the substrate encounters a first reactive gas A stream from the trailing first reactive gas port 800c. Thus, a single pass across the gas distribution plate 830 would result in a BC film formed on the surface.

The embodiment shown in FIG. 8 may have be operated with a either of the leading second gas port 802a or the trailing second gas port 802b initially supplying a purge gas P, instead of a reactive gas, to the substrate surface. In this case, a substrate traveling from left-to-right will encounter, in order (excluding purge and pump ports), a first reactive gas A from the leading first reactive gas port 800a to form a partial ALD layer on the substrate surface. The substrate then encounters a second reactive gas B from the leading second reactive gas port 802a. The second reactive gas B reacts with the partial ALD layer on the surface to form an ALD B layer. The substrate then encounters a first reactive gas A stream from the intermediate first reactive gas port 800b, a purge gas P stream from the trailing second reactive gas port 802b and a first reactive gas A stream from the trailing first reactive gas port 800c. In one or more embodiments, the substrate reverses course and contacts each of the gas streams in reverse, resulting in another B layer on the substrate. This full cycle can be repeated any number of times to result in a thicker B layer deposited on the substrate.

At this point, the flow of the leading second reactive gas B stream is stopped by closing the valve 806 connecting the second reactive gas B source to the leading gas manifold 804a. The purge gas P, if it is not already flowing, is then allowed to flow through the leading gas manifold 804a by opening the valve 806 connecting the purge gas P source to the gas manifold.

The flow of the purge gas P from the trailing second reactive gas port 802b is changed to include a third reactive gas C. The purge gas P can be turned off completely by closing the valve 806 connecting the purge gas P source to the trailing gas manifold 804b. Alternatively, the purge gas P can be left flowing at the same flow rate or a modified flow rate. The third reactive gas C is allowed to flow through the trailing gas manifold 802b by opening the valve 806 connecting the third reactive gas C source to the trailing gas manifold 802b.

With these changes, the substrate which has already had a BB cycle, is cycled again. Now the substrate passes a first reactive gas A stream from the leading first reactive gas port 800a, a purge gas P stream from the leading second reactive gas port 802b and a first reactive gas A stream from the intermediate first reactive gas port 800b. The substrate has now been exposed to three gas stream including the first reactive gas A since the last exposure to the second reactive gas B. Any or all of these gas streams can react with the substrate surface to form a partial ALD layer thereon. The substrate then encounters a third reactive gas C stream from the trailing second reactive gas port 802b. The third reactive gas C reacts with the partial ALD layer on the substrate to form a C layer. The substrate then encounters a first reactive gas A stream from the trailing first reactive gas port 800c. The cycle is completed by reversing course and exposing the substrate surface to each of these gas streams in reverse, creating another C layer on the substrate.

Following this scheme, the substrate has been exposed to a BBCC process which can be repeated any number of times to result in a film having a B:C ratio of 1:1. Additionally, the order of the processing can be reversed so that the C layer is deposited before the B layer.

Embodiments of this type may be of use in the deposition of a strontium titanate film. Here, the first reactive gas A is an oxidant (e.g., ozone or water), the second reactive gas B is a titanium precursor and the third reactive gas C is a strontium precursor. Thus, the substrate is exposed to oxidant/titanium precursor/oxidant/oxidant/titanium precursor/oxidant in the first cycle and oxidant/strontium precursor/oxidant/oxidant/strontium precursor/oxidant in the second cycle. This results in a 1:1 mixed film of titanium oxide and strontium oxide on the surface of the substrate. There are possible breaks in the cycle for annealing and/or additional alumina ALD deposition cycles. Embodiments of the invention have flexibility to not only achieve 1:1 ratio films but can be used to create any ratio of a A:B:C: . . . :X films depending of the number and order of the reactive gases used.

In some embodiments, the substrate does not move the entire length of the gas distribution plate for each process. For example, during the deposition of the B film in the example above, the substrate is exposed to a purge gas stream and an additional first reactive gas A stream twice, once in each direction. To save processing time, the substrate may move as far as necessary to form a B film and then reverse course before reaching the end of the gas distribution plate 830. Then, when the C film is being formed, the substrate may start after the first gas port of the gas distribution plate 830. If only one cycle is to be performed for each of B and C depositions, then the substrate will always start in front of the gas distribution plate, but does not need to end, or reverse course, after the gas distribution plate.

In another embodiment, separate gas manifolds are connected to the leading first reactive gas A port 800a and the trailing first reactive gas port 800c. The manifold can be used in the same fashion described for the second reactive gas ports. Therefore, the flow of the first reactive gas can be replaced with a purge gas when not needed, or can be changed to a different first reactive gas (e.g., a third, fourth or fifth reactive gas species). While this embodiment is not shown in the Figures, one can easily appreciate that the leading and trailing gas manifolds can be moved to the first reactant gas ports, or that additional gas manifolds may be connected to the first reactant gas ports, thus allowing the first reactant gas to be changed.

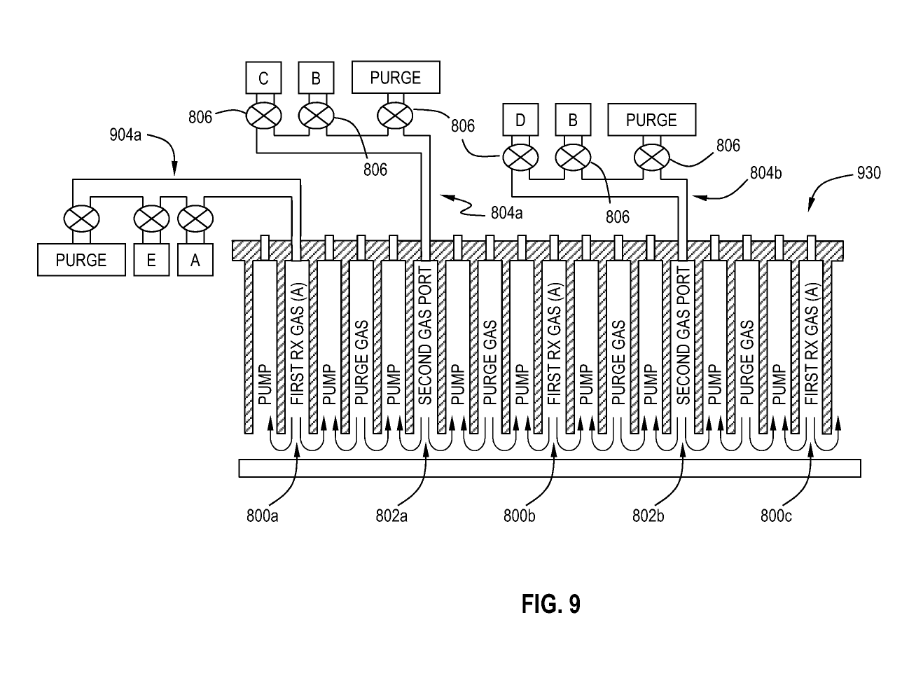

FIG. 9. shows another embodiment of the invention similar to that of FIG. 8. The gas distribution plate 930 here has multiple gas manifolds connected thereto. The leading gas manifold 804a and the trailing gas manifold 804b each have one additional reactive gas in fluid communication therewith. The additional leading and trailing reactive gas can be the same gas, or as shown in the Figure, can be different gases (i.e., C and D, respectively). Additionally, there is a gas manifold 904a connected to and in fluid communication with the first reactive gas port 800a. There can be multiple gases connected thereto in the same way described for the gas manifolds connected to the second reactive gas ports. An additional gas E is shown connected to the gas manifold 904a. This can be different from gas A in either identity, concentration or both. For example gas A may be water vapor and gas E may be ozone. Both are oxidants commonly used in ALD processes. For example, gas B may react with ozone but not water vapor, and gas C may react better with water vapor. While a single gas manifold 904 is shown connected to the first reactive gas port 800a, it will be understood that additional gas manifolds can be connected to the intermediate first reactive gas port 800b and the trailing first reactive gas port 800c. Connecting multiple gases through the manifold to any or all of the reactive gas port (both the first reactive gas port and the second reactive gas port) can allow for multiple processes to be performed in a single ALD chamber.

Embodiments of this sort may be used in the processing of, for example barium strontium titanate (BST) films or lead zirconium titanate (PZT) films. In BST films, where the various precursors include barium containing precursors, strontium containing precursors, titanium containing precursors, lead containing precursors and zirconium containing precursors. The precursors can be separated amongst the first reactive gas source, second reactive gas source, third reactive gas source and fourth reactive gas source, as will be understood by those skilled in the art.

Additional embodiments of the invention are directed to atomic layer deposition chambers comprising the gas distribution plate described above. A specific embodiment of the invention is directed to an atomic layer deposition system comprising a processing chamber with a gas distribution plate therein. The gas distribution plate comprises a plurality of gas injectors consisting essentially of, in order, a vacuum port, a purge gas injector, a vacuum port, a first reactive gas A port, a vacuum port, a purge port, a vacuum port, a second reactive gas port in fluid communication with a gas manifold which is in fluid communication with at least a second reactive gas B source and a purge gas P source, a vacuum port, a purge port, a vacuum port, a first reactive gas port, a vacuum port, a purge port and a vacuum port. As used in this specification and the appended claims, the term “consisting essentially of”, and the like, mean that the gas distribution plate 30 excludes additional reactive gas ports, but does not exclude non-reactive gas ports like purge gases and vacuum lines. Therefore, in the embodiment shown in FIG. 7, the addition of purge gases would still consist essentially of ABA, while the addition of a third reactive gas C injector would not consist essentially of ABA.

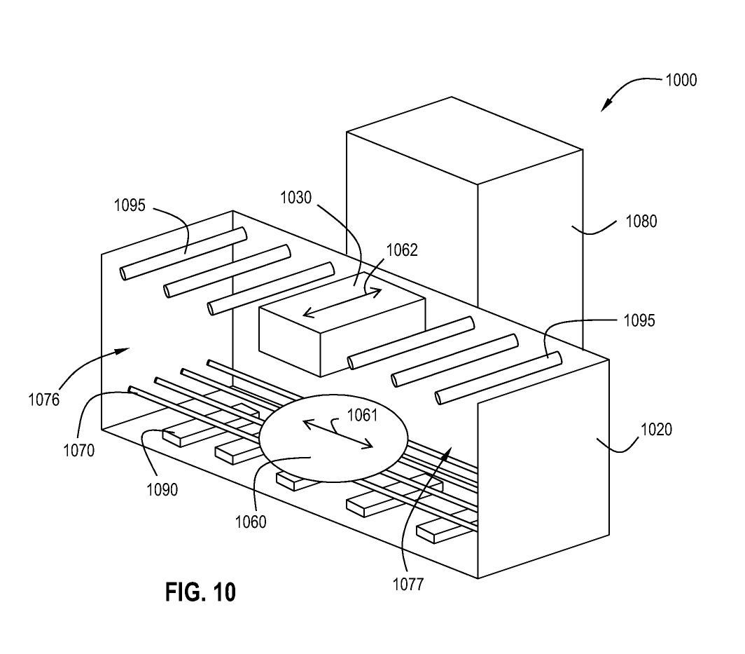

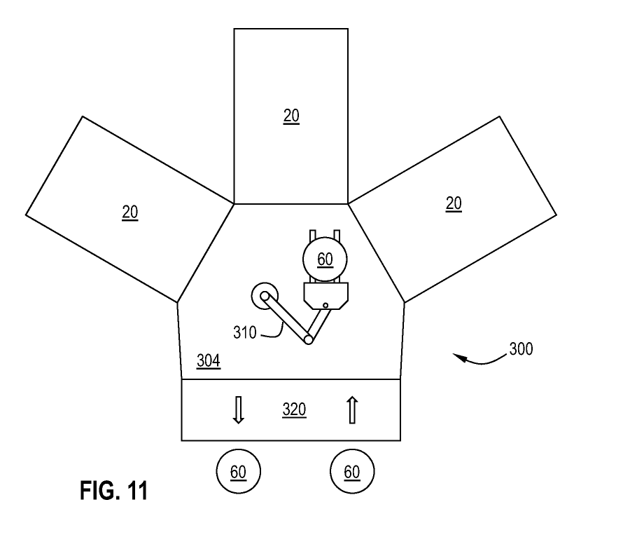

FIG. 10 shows an embodiment of an atomic layer deposition system 1000. Those skilled in the art will understand that this is merely a block representation of an ALD instrument, and no dimensions, orientations, or positions should be inferred from the drawing. The ALD system 1000 includes a processing chamber 1020 suitably sized to process a substrate 1060. A gas distribution plate 1030 is positioned within the processing chamber 1020. The gas distribution plate 1030 is shown roughly centered in the processing chamber 1020, but this is merely illustrative of one possible alignment. In some embodiments, the gas distribution plate 1030 is not centered in the processing chamber 1020.

The substrate 1060 is shown resting on four tracks 1070. The tracks are 1070 are capable of transporting the substrate 1060 from a region before 1076 of the gas distribution plate 1030 to a region after 1077 the gas distribution plate 1030. As described earlier with respect to FIG. 1, the tracks 1070 can be any suitable device for moving the substrate 1060 reciprocally with respect to the gas distribution plate 1030 and can be present in any number. The tracks 1070 move the substrate 1060 in a back and forth motion (arrow 1061) perpendicular to the axis that the elongate gas ports are aligned in. Arrow 1062 shows the axis that the elongate gas ports lie along.

A full stroke (back and forth paths) would result in a full cycle (2 layers) exposure to the substrate. In certain embodiments, rotational movement may also be employed after every stroke, or after multiple strokes. The rotational movement may be discrete movements, for example 10, 20, 30, 40, or 50 degree movements or other suitable incremental rotational movement. Such rotational movement together with linear movement may provide more uniform film formation on the substrate.

The substrate 1060 can be supported on any suitable support including, but not limited to, a susceptor like that shown in FIG. 2. No support is shown in FIG. 10 for clarity of illustration. The substrate 1060 is shown a large distance from the gas distribution plate 1030, but it will be understood that the distance between the gas distribution plate 1030 and the substrate 1060 is generally small to avoid diffusion of the reaction gases in the processing chamber 1020. The relatively large distance is illustrated for illustration purposes only.

The processing chamber 1020 shown includes a plurality of heaters 1090 below the path of the substrate 1060. These heaters 1090 are used to maintain a desired temperature in the processing chamber 1020. In particular, the heaters 1090 are used to maintain a specific temperature in the region below the gas distribution plate 1030 to ensure consistent temperature for the ALD reactions. The heaters can be any suitable devices known to those skilled in the art.

Thermal elements (not shown) can be distributed along the gas distribution plate 1030 to locally heat or cool a small region of the substrate during deposition. For example, one of the reactions may occur only at elevated temperatures, and to avoid overtaxing the thermal budget of the substrate (or device being formed) the temperature is elevated only when necessary. Another example is an atomic layer etch in which a deposition layer is formed on the substrate surface and elevated temperature vaporizes the layer to etch the substrate surface.

The processing chamber 1020 shown in FIG. 10 includes at least one energy source 1095. As used in this specification and the appended claims, the term “energy source” is used to describe a component capable of treating the wafer before, during and/or after deposition. For example, a plurality of energy sources 1095 can be positioned in the region adjacent the gas distribution plate and can be used to heat/anneal/cure the film on the substrate during or after deposition. The energy sources are positioned above the substrate 1060 in one or more of the region before 1076 and in the region after 1077 the gas distribution plate 1030. Stated differently, the energy sourc(s) are positioned adjacent the gas distribution plate 1030, or in a region adjacent the gas distribution plate 1030. Although there are three individual energy sources 1095 shown on each side of the gas distribution plate 1030, it should be understood that this is merely one possible embodiment and that there can by any suitable number of energy sources. The energy sources 1095 are illustrated as being cylindrical, but it will be understood that this is for illustrative purposes only and no structure is implied

In some embodiments, there is at least one energy source 1095 positioned in the region before 1076 the gas distribution plate 1030. In one or more embodiments, there is at least one energy source positioned in the region after 1077 the gas distribution plate. The at least one energy source 1095 can be any suitable energy source, including, but not limited to, heat lamps, tungsten-halogen lamps, IR lamps, UV lamps/sources, arc lamps, resistive heaters, light sources with different wavelengths, light sources with different exposure times (lasers, flash lamps, etc.), rastering or pulsed lasers. There can be any number of energy sources 1095 adjacent the gas distribution plate 1030. Each of the energy sources can be the same type (e.g., two laser), different types (e.g., one laser and one resistive heater) or a combination of the same type of energy sources and different energy sources types (e.g., two linear heat sources and one flash lamp). Each of the energy sources, independently, can be operating constantly or intermittently throughout processing. In detailed embodiments, the energy source 1095 is a linear heating source which has an axis perpendicular to the axis of movement of the substrate, see arrow 1061.

The energy source 1095 can be useful during processing to anneal the deposited film after formation. Typically, an atomic layer deposition process would require multiple passes beneath the gas distribution plate 1030 to form a layer of sufficient thickness. The deposited layer may then be annealed to form a more uniform film. By including the energy sources 1095, one either or both sides of the gas distribution plate 1030, the deposited film can be annealed after every pass beneath the gas distribution plate 1030. In some embodiments, the deposition film is annealed after every nth pass beneath the gas distribution plate, where n is in the range of 1 to the total number of passes beneath the gas distribution plate.

The energy sources 1095 can be used to provide a second deposition temperature for a process without the need to change the process temperature of the entire processing chamber 1020. For example, a B film is to be formed at the temperature of the processing chamber. The substrate moves back and forth to deposit the B layers. If the next layer, a C layer, is to be deposited at a higher temperature, the substrate 1060 temperature can be elevated by the energy sources 1095 before the next deposition cycle.

The use of the energy source 1095 can result in overheating the substrate, depending on the specific energy source and length of exposure. If necessary, the substrate may be supported on a susceptor or edge ring to disperse excess heat. Additionally, the substrate may rest on a susceptor which acts as a cooling plate. In one or more embodiments, the substrate 1060 sits on a plurality of pins (not shown) which elevate the substrate. When elevated, it may be easier to anneal at higher temperature than the process temperature.

A control system 1080 is shown connected to the processing chamber 1020. The control system 1080 can include a gas management system, meaning all of the hardware necessary to provide the various processing gases to the gas distribution plate 1030. The gas manifolds connected to the first reactive gas ports and the second reactive gas ports can be maintained within the control system. Thus, the gas manifold may not be located within the processing chamber 1020, but adjacent to the processing chamber. The control system 1080 may also include circuitry to control the heaters 1090 and the energy sources 1095. The control system 1080 may also include the necessary components to drive the substrate through the processing chamber. In some embodiments, the control system 1080 comprises a computer with a central processing unit, suitable storage devices and electrical connections to interact with the processing chamber and gas management hardware. The computer system can be a central programming point where the operator can enter the process method specifics (e.g., what gases, flow rates, number of deposition cycles, etc.) and a processing sequence (e.g., changing of the gases and the number of substrates to be processed).

Additional embodiments of the invention are directed to cluster tools comprising at least one atomic layer deposition system described. The cluster tool has a central portion with one or more branches extending therefrom. The branches being deposition, or processing, apparatuses. Cluster tools which incorporate the short stroke motion require substantially less space than tools with conventional deposition chambers. The central portion of the cluster tool may include at least one robot arm capable of moving substrates from a load lock chamber into the processing chamber and back to the load lock chamber after processing. Referring to FIG. 16, an illustrative cluster tool 300 includes a central transfer chamber 304 generally including a multi-substrate robot 310 adapted to transfer a plurality of substrates in and out of the load lock chamber 320 and the various process chambers 20. Although the cluster tool 300 is shown with three processing chambers 20, it will be understood by those skilled in the art that there can be more or less than 3 processing chambers. Additionally, the processing chambers can be for different types (e.g., ALD, CVD, PVD) of substrate processing techniques.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. A gas distribution plate, comprising:
a plurality of elongate gas ports including at least one first reactive gas port in fluid communication with a first reactive gas and at least one second reactive gas port in fluid communication with a gas manifold, the gas manifold in fluid communication with at least a second reactive gas different from the first reactive gas and a purge gas.

2. The gas distribution plate of claim 1, wherein the gas manifold is in fluid communication with a third reactive gas different from the first reactive gas and the second reactive gas and optionally a fourth reactive gas different from the first reactive gas, the second reactive gas and the third reactive gas.

3. The gas distribution plate of claim 1, wherein the gas manifold comprises at least one switching valve configured to block fluid communication between the gas manifold and each of the second reactive gas and the purge gas so that no gas or a single gas is in flow communication with the gas manifold.

4. The gas distribution plate of claim 1, wherein there is a leading second reactive gas port and a trailing second reactive gas port with a first reactive gas port on either side of the leading second reactive gas port and the trailing second reactive gas port.

5. The gas distribution plate of claim 4, wherein the leading second reactive gas port is in fluid communication with a leading gas manifold and the trailing second reactive gas port is in fluid communication with a trailing gas manifold, the leading gas manifold being in fluid communication with at least a second reactive gas, a purge gas and at least one additional leading reactive gas different from the first reactive gas and the second reactive gas, and the trailing gas manifold in fluid communication with at least a second reactive gas, a purge gas and at least one additional trailing reactive gas different from the first reactive gas and the second reactive gas.

6. The gas distribution plate of claim 5, wherein the additional leading reactive gas and the additional trailing reactive gas are the same.

7. The gas distribution plate of claim 5, wherein the additional leading reactive gas is different from the additional trailing reactive gas.

8. The gas distribution plate of claim 1, wherein a substrate moving from a region in front of the gas distribution plate to a region behind the gas distribution plate is exposed to the plurality of gas injectors including, in order, a leading first reactive gas port followed by at least one second reactive gas port unit, the second reactive gas port unit consisting essentially of (1) the second reactive gas port in fluid communication with a gas manifold, the gas manifold in fluid communication with at least a reactive gas different from the first reactive gas and a purge gas, and (2) a trailing first reactive gas port.

9. The gas distribution plate of claim 8, wherein the gas manifold of each of the at least one second reactive gas port units is in fluid communication with at least one additional reactive gas.

10. The gas distribution plate of claim 8, wherein there is one second reactive gas port unit.

11. The gas distribution plate of claim 8, wherein there are at least two second reactive gas port units.

12. The gas distribution plate of claim 11, wherein each of the second reactive gas port units comprises a different reactive gas.

13. The gas distribution plate of claim 1, wherein a substrate moving from a region in front of the gas distribution plate to a region in back of the gas distribution plate is exposed, in order, to the plurality of gas injectors consisting essentially of:
(1) a leading first reactive gas port,
(2) a leading second reactive gas port in fluid communication with a leading gas manifold, the leading gas manifold in fluid communication with at least a second reactive gas different from the first reactive gas and a purge gas,
(3) an intermediate first reactive gas port,
(4) a trailing second reactive gas port in fluid communication with a trailing gas manifold, the trailing gas manifold in fluid communication with at least a third reactive gas and a purge gas, the third reactive gas being different from the first reactive gas and the second reactive gas, and
(5) a trailing first reactive gas port.

14. An atomic layer deposition system, comprising a processing chamber with the gas distribution plate of claim 1 therein and a substrate carrier configured to move a substrate reciprocally with respect to the gas distribution plate in a back and forth motion perpendicular to an axis of the elongate gas ports.

15. The atomic layer deposition system of claim 14, wherein the gas manifold is in fluid communication with at least a third reactive gas different from the second reactive gas and the first reactive gas.

16. The atomic layer deposition system of claim 14, further comprising at least one energy source located in one or more of a region before the gas distribution plate and a region after the gas distribution plate.

17. The atomic layer deposition system of claim 16, wherein the at least one energy source is selected from the group consisting of resistive heaters, radiative heaters, ultraviolet sources, laser sources, flash lamp, linear light sources and combinations thereof.

18. A method of processing a substrate comprising:
passing a portion of a substrate across a gas distribution plate in a first direction so that the portion of the substrate is exposed to, in order, a leading first reactive gas stream from a leading first reactive gas port, a second reactive gas stream different from the first reactive gas stream from a second reactive gas port and a trailing first reactive gas stream from a trailing first reactive gas port to deposit a first layer;
purging the second reactive gas stream from the second reactive gas port and providing a third reactive gas through the second reactive gas port, the third reactive gas different from the first reactive gas and the second reactive gas; and
passing the portion of the substrate across the gas distribution plate in a second direction opposite of the first direction so that the portion of the substrate is exposed to, in order, the trailing first reactive gas stream from the trailing first reactive gas port, the third reactive gas stream from the second reactive gas port and the leading first reactive gas stream from the leading first reactive gas port to create a second layer.

19. The method of claim 18, further comprising exposing the portion of the substrate to a purge gas stream between each of the first reactive gas streams and the second reactive gas stream and between each of the first reactive gas streams and the third reactive gas stream.

20. A method of processing a substrate comprising:
passing a portion of the substrate across a gas distribution plate in a first direction so that the portion of the substrate is exposed to, in order, a leading first reactive gas stream from a leading first reactive gas port, a leading second reactive gas stream from a second reactive gas port, an intermediate first reactive gas stream from an intermediate first reactive gas port, a purge gas from a trailing second reactive gas port and a trailing first reactive gas stream from a trailing first reactive gas port;
purging the second reactive gas stream from the leading second reactive gas port so that a purge gas flows from the leading second reactive gas port;
changing the purge gas flowing from the trailing second reactive gas port to a third reactive gas different from the first reactive gas and the second reactive gas; and
passing the portion of the substrate across the gas distribution plate in a second direction opposite of the first direction so that the portion of the substrate is exposed to, in order, a trailing first reactive gas stream from a trailing first reactive gas port, a third reactive gas stream from the trailing second reactive gas port, an intermediate first reactive gas stream from the intermediate first reactive gas port, a purge gas stream from the leading second reactive gas port and a leading first reactive gas stream from a leading first reactive gas port.
